(19) United States
(12) Patent Application Publication
(10) Pub. No.: US 2011/0026385 A1
(43) Pub. Date: Feb. 3, 2011

(54) SEMICONDUCTOR STORAGE DEVICE, SEMICONDUCTOR DEVICE AND OPTICAL DISC REPRODUCING DEVICE

(76) Inventors: Nobuyuki Nakai, Osaka (JP); Hiroyuki Sadakata, Osaka (JP)

Correspondence Address: MCDERMOTT WILL & EMERY LLP, 600 13TH STREET, NW, WASHINGTON, DC, 20005-3096, US

(21) Appl. No.: 12/937,174

(22) PCT Filed: Jun. 11, 2009
(86) PCT No.: PCT/JP2009/002652

§ 371 Date: Oct. 8, 2010

(30) Foreign Application Priority Data
Jun. 12, 2008 (JP) 2008-154089

(51) Int. Cl. G11C 7/00; G11B 20/10

(52) U.S. Cl. 369/47.32; 365/222; G9B/20.009

(57) ABSTRACT

A semiconductor storage device including a memory cell and having a function of refreshing the memory cell, includes a clock generation circuit configured to receive a first clock, generate a second clock based on an inversion of the first clock, and output the second clock. The semiconductor storage device performs operation of the refresh function in synchronization with at least one of the first and second clocks.

### RELATED APPLICATIONS

This application is the U.S. National Phase under 35 U.S.C. §371 of International Application No. PCT/JP2009/002652, filed on Jun. 11, 2009, which in turn claims the benefit of Japanese Application No. 2008-154089, filed on Jun. 12, 2008, the disclosures of which Applications are incorporated by reference herein.

### TECHNICAL FIELD

The present invention relates to the refreshing function of semiconductor storage devices. For example, the present invention relates to reduction or prevention of a decrease in a data transfer rate even when a semiconductor device in which a semiconductor storage device is provided has a low operating frequency specification, and also, simplification of layout design caused by a reduction in power consumption or power leveling, and circuit operation contributing to noise reduction.

### BACKGROUND ART

In recent years, the increase in the integration density of semiconductor devices by advances in microfabrication technologies has been spurred by competition between semiconductor manufacturers. Among other things, there are semiconductor devices called system LSIs in which a microprocessor, an application specific integrated circuit (ASIC), a custom logic circuit, or the like is mounted along with a large-capacity memory on a single semiconductor chip. Such devices have attracted attention of manufacturers because of their possibility that added values would enhance and differentiate the performance of products mounted thereon.

When such semiconductor devices are designed, memories mounted on the devices, which are categorized as dynamic random access memories (DRAMs), read only memories (ROMs), static random access memories (SRAMs), and the like, are used as a hardware library and need to satisfy various requirements.

In addition, system LSIs are mainly applied to audio/visual (AV) apparatuses, which have short product cycles, which holds true for the mounted hardware library. More specifically, the applications of system LSIs encompass consumer products and in-car products, particularly optical disk recording and reproducing devices, digital televisions, digital cameras, digital audio apparatuses, and the like. Efficient development of a hardware library including semiconductor storage devices which can be applied in common to a wide variety of system LSIs, plays a crucial role in improving the profitability of the manufacturer.

Note that the foregoing description is only for illustrating applications of the semiconductor storage device of the present invention and is not intended to limit the applications or use of the present invention.

Next, a basic circuit configuration of a conventional semiconductor device including a DRAM is shown in FIG. 1. In FIG. 1, a reference character 101 indicates a memory cell region in which memory cells are arranged in a matrix, a reference character 102 indicates a row decoder circuit which outputs a select signal for selecting one of groups of memory cells arranged in the row direction in the memory cell region 101, a reference character 103 indicates a column decoder circuit which outputs a select signal for selecting one of groups of memory cells arranged in the column direction in the memory cell region 101, a reference character 104 indicates a sense read/write amplifier circuit which reads and writes data from and to a memory cell selected and identified by the row decoder circuit 102 and the column decoder circuit 103, a reference character 105 indicates an internal data input/output line, a reference character 106 indicates an external data input/output line, a reference character 107 indicates a data input/output circuit which transmits and receives data to and from the sense read/write amplifier circuit 104 and receives and outputs the data via the external data input/output line 106 from and to a large-scale logic circuit region 124, a reference character 108 indicates a row address which identifies one of groups of memory cells arranged in the row direction for the row decoder circuit 102, a reference character 109 indicates a column address which identifies one of groups of memory cells arranged in the column direction for the column decoder circuit 103, a reference character 110 indicates an address control signal, a reference numeral 111 indicates an address input circuit which outputs the row address 108 to the row decoder circuit 102, and the column address 109 to the column decoder circuit 103 in accordance with the address control signal 110, a reference character 112 indicates an external control signal, a reference character 113 indicates a control circuit which outputs the address control signal 110 in accordance with the external control signal 112, a reference character 114 indicates an internal address control signal, a reference character 115 indicates a refresh circuit which generates the internal address control signal 114 equivalent to the address control signal 110 on standby to perform refresh operation with respect to the memory cell region 101, a reference character 116 indicates a timing adjustment signal, a reference character 117 indicates a timing generation circuit which outputs the timing adjustment signal 116 to perform timing adjustment with respect to the address input circuit 111, the control circuit 113, and the refresh circuit 115, a reference character 118 indicates an internal synchronization clock signal, a reference character 119 indicates a clock generation circuit which outputs the internal synchronization clock signal 118 to synchronize the data input/output circuit 107, the address input circuit 111, the control circuit 113, the refresh circuit 115, and the timing generation circuit 117, a reference character 120 indicates an external clock signal, a reference character 121 indicates a memory array region including the memory cell region 101, the row decoder circuit 102, the column decoder circuit 103, the sense read/write amplifier circuit 104, and the data input/output circuit 107, a reference character 122 indicates a control region including the address input circuit 111, the control circuit 113, the refresh circuit 115, the timing generation circuit 117, and the clock generation circuit 119, a reference character 123 indicates a semiconductor storage device including the memory array region 121 and the control region 122, a reference character 124 indicates a large-scale logic circuit region including standard cells, a reference character 125 indicates a redundancy replacement address storage circuit, a reference character 126 indicates a redundancy replacement address line which connects the redundancy replacement address storage circuit 125 to the memory array region 121, a reference character 127 indicates external terminals which are connected to the semiconductor storage device 123 or the large-scale logic circuit region 124, and a reference character 128 indicates a semiconductor device including the semiconductor storage device 123, the large-scale logic circuit region 124, the redundancy replacement address storage circuit 125, and the external terminals 127.

Here, the clock generation circuit 119 is provided when, for example, the capability of driving the control circuit 113 or the like is required. Specifically, for example, the clock generation circuit 119 includes a buffer circuit and outputs the internal synchronization clock signal 118 having the same logic level as that of the input external clock signal 120.

The operation will be briefly described with reference to FIG. 1.

In accordance with the external clock signal 120 input from the external terminals 127, the clock generation circuit 119 outputs and supplies the internal synchronization clock signal 118 as a clock for synchronizing the data input/output circuit 107, the address input circuit 111, the control circuit 113, the refresh circuit 115, and the timing generation circuit 117. The control circuit 113 generates and inputs the address control signal 110 to the address input circuit 111 in accordance with the external control signal 112 as well as the internal synchronization clock signal 118.

The address input circuit 111 generates and inputs the row address 108 to the row decoder circuit 102, and generates and inputs the column address 109 to the column decoder circuit 103. A memory cell in the memory cell region 101 is selected, corresponding to the values input to the row decoder circuit 102 and the column decoder circuit 103. Read/write operation is performed between the memory cell and the sense read/write amplifier circuit 104. Data input/output operation is performed between the sense read/write amplifier circuit 104 and the large-scale logic circuit region 124 via the internal data input/output line 105, the data input/output circuit 107, and the external data input/output line 106.

The refresh circuit 115 operates basically in the same manner as that described above, i.e., by the internal address control signal 114 being input to the address input circuit 111, operation similar to that which is performed when the address control signal 110 is input to the address input circuit 111 is performed. The two operations are different in that read data input to the sense read/write amplifier circuit 104 is only written to the memory cell, and data input/output operation is not performed between the sense read/write amplifier circuit 104 and the large-scale logic circuit region 124 via the internal data input/output line 105, the data input/output circuit 107, and the external data input/output line 106.

Operation of the redundancy replacement address storage circuit 125 and the redundancy replacement address line 126 will not be described.

In the semiconductor storage device having the aforementioned operation, the memory array region 121 and the large-scale logic circuit region 124 are provided on a single semiconductor integrated circuit, and therefore, the external data input/output line 106 can be relatively easily adapted to serve a multi-bit bus. Therefore, the frequency of the clock signal can be easily decreased to reduce the power consumption while ensuring a sufficient data transfer rate.

### Citation List

### Patent Document

PATENT DOCUMENT 1: Japanese Patent Publication No. H08-138374

### SUMMARY OF THE INVENTION

### Technical Problem

However, the refresh operation of the memory array region 121 needs to be performed at a predetermined frequency, i.e., a predetermined number of times every predetermined cycle. The refresh frequency is constant irrespective of the frequency of the clock signal. Therefore, as the clock signal frequency is decreased, a band (e.g., the proportion of clock pulses used) in which operation other than the refresh operation is performed, such as data transfer and the like, decreases.

Specifically, if, for example, as shown in FIG. 2, refresh operation needs to be performed twice with 2 clocks per 20 clock pulses with respect to the external clock signal 120 having a predetermined frequency, operation such as a command process and the like can be performed with the remaining 18 clock pulses, i.e., 90% of the band. In contrast to this, if, for example, as shown in FIG. 3, the frequency of the external clock signal 120 is decreased by a factor of 4, 3 clock pulses per 5 clock pulses can be used for a command process and the like, i.e., the available proportion of the band is decreased to 60%.

Therefore, it is difficult to largely decrease the clock signal frequency to reduce the power consumption. In particular, for example, even when the data amount of a signal to be processed is dramatically small (e.g., the semiconductor device processes an audio signal rather than a video signal), it is difficult to largely decrease the clock signal frequency. This problem becomes more significant in the case of, for example, a semiconductor device employed in an apparatus in which the data amount to be processed is small and a reduction in the power consumption is highly required, such as a mobile apparatus which processes an audio signal, and the like.

The present invention has been made in view of the aforementioned problem. It is an object of the present invention to appropriately refresh a memory and easily reduce the clock signal frequency while, for example, ensuring a sufficient data transfer rate.

### SOLUTION TO THE PROBLEM

To achieve the object, a first example of the present invention is a semiconductor storage device including a memory cell and having a function of refreshing the memory cell, which includes a clock generation circuit configured to receive a first clock, generate a second clock based on an inversion of the first clock, and output the second clock. The semiconductor storage device performs operation of the refresh function in synchronization with at least one of the first and second clocks.

As a result, in the case of a low-speed frequency specification, the decrease in the data transfer rate is reduced, and in a semiconductor device including the semiconductor storage device, the performance is advantageously improved while the reduction in the power consumption is maintained.

A second example of the present invention is the semiconductor storage device of the first example of the present invention, further including a select circuit configured to select one of the first and second clocks in synchronization with which the refresh operation is to be performed, in accordance with a control signal.

As a result, in the case of a low-speed frequency specification, the decrease in the data transfer rate is reduced, and by adding a simple circuit, the performance is advantageously improved while the reduction in the power consumption is maintained.

A third example of the present invention is a semiconductor device including the semiconductor storage device of the second example of the present invention, a logic circuit and an TO block including an input/output circuit configured to receive and output a signal from and to the outside, and an electrode pad connected to the input/output circuit. An external signal input via the TO block is input to the logic circuit, and the control signal which controls the selection of the select circuit is generated.

As a result, a control can be advantageously easily achieved.

A fourth example of the present invention is the semiconductor device of the third example of the present invention further including a PLL circuit configured to generate a clock having a frequency which is controlled in accordance with the external signal input via the TO block, and input the clock to the semiconductor storage device and the logic circuit.

As a result, the frequency of a clock input to the semiconductor storage device or the logic circuit can be advantageously easily changed.

A fifth example of the present invention is the semiconductor device of any one of the third and fourth examples of the present invention including any combination of the semiconductor storage device configured to perform the refresh operation in synchronization with the first clock, and the semiconductor storage device configured to perform the refresh operation in synchronization with the second clock.

As a result, current consumption caused by refresh operation can be distributed on a time axis, and therefore, the power consumption of the semiconductor device can be advantageously leveled.

A sixth example of the present invention is an optical disk reproducing device including a semiconductor device including a semiconductor storage circuit having a function of refreshing a memory cell, a logic circuit, an IO block including an input/output circuit configured to receive and output a signal and an electrode pad connected to the input/output circuit, and a PLL circuit configured to generate a clock and change a frequency of the clock in accordance with a control signal, an optical pickup, and a circuit configured to output a signal which can be used to discriminate between a plurality of types of information recording media based on a data signal read by the optical pickup. The semiconductor storage circuit includes a clock generator configured to receive a first clock, generate a second clock based on an inversion of the first clock, and output the second clock, and a select circuit configured to select one of the first and second clocks in synchronization with which the refresh operation is to be performed, in accordance with a control signal. The signal which can be used to discriminate between a plurality of types of information recording media is input as an external signal to the IO block of the semiconductor device. The external signal is input to the logic circuit, the control signal to be input to the select circuit of the semiconductor storage device is generated, and the refresh operation of the semiconductor storage device is controlled in accordance with the control signal.

As a result, the leveling and reduction of the current consumption can be advantageously achieved, depending on operating conditions.

A seventh example of the present invention is an optical disk reproducing device including a semiconductor device including a semiconductor storage circuit having a function of refreshing a memory cell, a logic circuit, an IO block including an input/output circuit configured to receive and output a signal and an electrode pad connected to the input/output circuit, and a PLL circuit configured to generate a clock and change a frequency of the clock in accordance with a control signal, an optical pickup, and a circuit configured to output a signal which can be used to discriminate between a plurality of types of information recording media based on a data signal read by the optical pickup. The semiconductor storage circuit includes a clock generator configured to receive a first clock, generate a second clock based on an inversion of the first clock, and output the second clock, and a select circuit configured to select one of the first and second clocks in synchronization with which the refresh operation is to be performed, in accordance with a control signal. The signal which can be used to discriminate between a plurality of types of information recording media is input as an external signal to the IO block of the semiconductor device. A frequency of a clock input to the semiconductor storage device and the logic circuit is changed in accordance with the external signal.

As a result, the leveling and reduction of the current consumption can be advantageously achieved, depending on operating conditions.

An eighth example of the present invention is the semiconductor storage device of the first example of the present invention in which the clock generation circuit generates the second clock containing two pulses per clock cycle.

A ninth example of the present invention is the semiconductor storage device of the eighth example of the present invention in which the clock generation circuit includes a NOT circuit configured to invert the first clock to output an inverted signal, and an EXNOR circuit configured to generate the second clock based on the first clock and the inverted signal.

A tenth example of the present invention is the semiconductor storage device of the eighth example of the present invention in which the clock generation circuit includes a selector configured to select one of the first and second clocks.

As a result, for example, the efficiency of the clock signal can be increased.

An eleventh example of the present invention is the semiconductor storage device of the tenth example of the present invention in which the selector performs the selection in accordance with a control signal input from the outside of the semiconductor storage device.

As a result, it is possible to easily control whether to increase the efficiency of the clock signal.

A twelfth example of the present invention is the semiconductor storage device of the tenth example of the present invention in which the selector is configured to fixedly select one of the first and second clocks during the refresh operation.

As a result, the aforementioned circuit can be caused to function as a buffer or the like, and the efficiency of the clock signal can be increased.

A thirteenth example of the present invention is the semiconductor storage device of the eighth example of the present invention in which the clock generation circuit includes a selector, the clock generation circuit is configured to generate a third clock which transitions at a timing different from a transition timing of the first clock to cause the refresh operation, and the selector selects one of the first, second, and third clocks.

A fourteenth example of the present invention is the semiconductor storage device of the thirteenth example of the present invention in which the clock generation circuit includes a NOT circuit configured to invert the first clock to generate and output an inverted signal, and a NOR circuit configured to generate the third clock based on the first clock and the inverted signal.

As a result, the efficiency of the clock signal can be increased, and the current can be distributed during refresh operation.

A fifteenth example of the present invention is the semiconductor storage device of the thirteenth example of the present invention in which the selector selects one of the first and second clocks.

As a result, for example, operation similar to that of the device of the eleventh example of the present invention can be performed using a device which can generate the third clock.

A sixteenth example of the present invention is the semiconductor storage device of the thirteenth example of the present invention in which first and second pairs of the memory cell and the clock generation circuit are provided, the selector for the first pair fixedly selects the first clock, and the selector for the second pair selects one of the first and third clocks during the refresh operation.

A seventeenth example of the present invention is the semiconductor storage device of the sixteenth example of the present invention in which the selector for the second pair is configured to fixedly select the third clock during the refresh operation.

As a result, the current can be distributed during refresh operation.

An eighteenth example of the present invention is a semiconductor device including the semiconductor storage device of the tenth example of the present invention. The selector selects the first clock when the first clock has a first frequency, and the second clock when the first clock has a second frequency lower than the first frequency.

A nineteenth example of the present invention is an optical disk reproducing device including the semiconductor device of the eighteenth example of the present invention, an optical pickup configured to read information recorded in a recording medium, and a determination circuit configured to determine a frequency of a clock to be supplied to the semiconductor storage device in the semiconductor device so that the information read from the recording medium is processed, and output a determination signal. The selector selects the first or second clock, depending on the determination signal.

A twentieth example of the present invention is the optical disk reproducing device of the nineteenth example of the present invention further including a PLL circuit configured to generate the first clock having a frequency depending on the determination signal.

As a result, when the frequency of the first clock is low, the efficiency of the clock signal can be increased.

### ADVANTAGES OF THE INVENTION

According to the present invention, in the case of a low-speed frequency specification, the decrease in the data transfer rate is reduced, and in a semiconductor device including a semiconductor storage device, the performance is advantageously improved while the reduction in the power consumption is maintained, for example.

### BRIEF DESCRIPTION OF THE DRAWINGS

FIG. 1 is a block diagram showing a configuration of a semiconductor device 128 including a conventional semiconductor storage device 123.

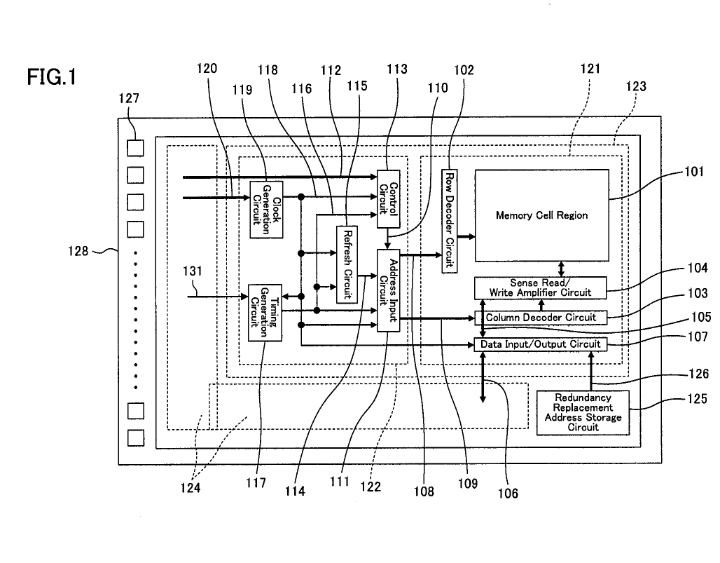

FIG. 2 is a timing chart showing example signals of main parts of the conventional semiconductor storage device 123.

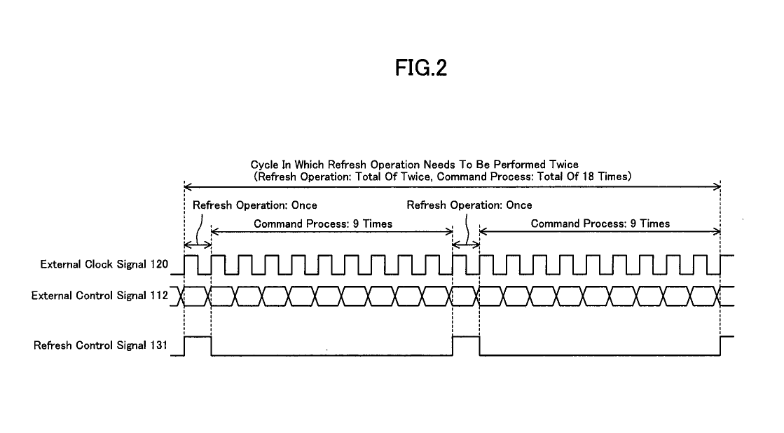

FIG. 3 is a timing chart showing other example signals of the main parts of the conventional semiconductor storage device 123.

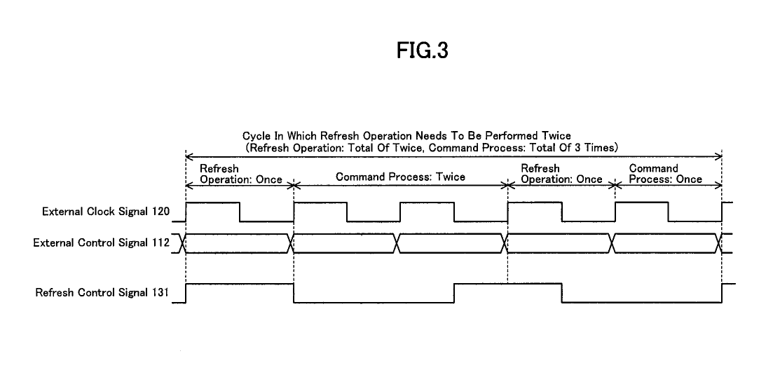

FIG. 4 is a block diagram showing a configuration of a semiconductor device 628 according to a first embodiment of the present invention.

FIG. 5 is a circuit diagram showing a configuration of a clock generation circuit 619 provided in a semiconductor storage device 623 of the semiconductor device 628.

FIG. 6 is a timing chart showing example signals of parts of the clock generation circuit 619 when the frequency of a clock signal is high.

FIG. 7 is a timing chart showing example signals of the parts of the clock generation circuit 619 when the frequency of the clock signal is low.

FIG. 8 is a block diagram showing a configuration of an optical disk reproducing device including the semiconductor device 628.

FIG. 9 is a block diagram showing a configuration of a semiconductor device 628 according to a second embodiment of the present invention.

FIG. 10 is a circuit diagram showing a configuration of a clock generation circuit 819 provided in semiconductor storage devices 623 and 623′ of the semiconductor device 628.

FIG. 11 is a timing chart showing example signals of parts of the clock generation circuit 819 when the frequency of a clock signal is high.

FIG. 12 is a timing chart showing example signals of the parts of the clock generation circuit 819 when the frequency of the clock signal is low.

### DESCRIPTION OF EMBODIMENTS

Embodiments of the present invention will be described in detail hereinafter with reference to the accompanying drawings. Note that, in each of the embodiments described below, components having functions similar to those of other embodiments are indicated by the same reference characters and will not be repeatedly described.

### First Embodiment of the Invention

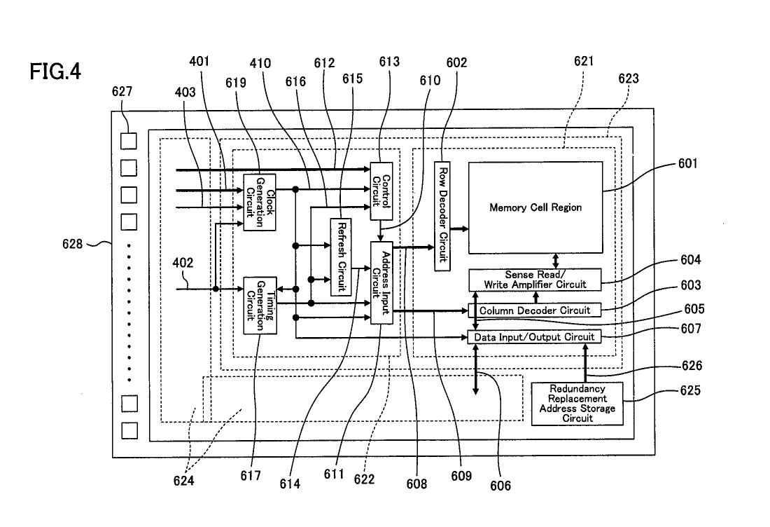

As a first embodiment of the present invention, a semiconductor device 628 including a semiconductor storage device 623, and an optical disk reproducing device including the semiconductor device 628 will be described with reference to FIGS. 4-8. In this example, a dynamic random access memory (DRAM) is used as the semiconductor storage device 623.

(Configuration of Semiconductor Device 628)

Firstly, a configuration of the semiconductor device 628 will be described. FIG. 4 is a block diagram showing the configuration of the semiconductor device 628. The semiconductor device 628 includes, in addition to the semiconductor storage device 623, a large-scale logic circuit region 624, a redundancy replacement address storage circuit 625, and external terminals 627.

(Configuration of Semiconductor Storage Device 623 in Semiconductor Device 628)

The semiconductor storage device 623 includes a memory array region 621 and a control region 622.

In the memory array region 621, a reference character 601 indicates a memory cell region in which memory cells are arranged in a matrix, a reference character 602 indicates a row decoder circuit which outputs a select signal for selecting one of groups of memory cells arranged in the row direction in the memory cell region 601, a reference character 603 indicates a column decoder circuit which outputs a select signal for selecting one of groups of memory cells arranged in the column direction in the memory cell region 601, a reference character 604 indicates a sense read/write amplifier circuit which reads and writes data from and to a memory cell selected and identified by the row decoder circuit 602 and the column decoder circuit 603, a reference character 605 indicates an internal data input/output line, a reference character 606 indicates an external data input/output line, and a reference character 607 indicates a data input/output circuit which transmits and receives data to and from the sense read/write amplifier circuit 604 and receives and outputs the data via the external data input/output line 606 from and to the large-scale logic circuit region 624.

In the control region 622, a reference character 608 indicates a row address which identifies one of groups of memory cells arranged in the row direction for the row decoder circuit 602, a reference character 609 indicates a column address which identifies one of groups of memory cells arranged in the column direction for the column decoder circuit 603, a reference character 610 indicates an address control signal which indicates a memory cell from or to which data is to be read or written, in accordance with an instruction from the outside of the semiconductor storage device 623, a reference character 611 indicates an address input circuit which outputs the row address 608 to the row decoder circuit 602, and the column address 609 to the column decoder circuit 603 in accordance with the address control signal 610 (or an internal address control signal 614 described below), a reference character 612 indicates an external control signal 612 which indicates an instruction to, for example, read or write data, a reference character 613 indicates a control circuit which outputs the address control signal 610 in accordance with the external control signal 612, a reference character 614 indicates an internal address control signal which indicates a memory cell to be refreshed and is equivalent to the address control signal 610, a reference character 615 indicates a refresh circuit which generates the internal address control signal 614 to cause the memory cell region 601 to perform refresh operation, a reference character 616 indicates a timing adjustment signal, a reference character 617 indicates a timing generation circuit, a reference character 619 indicates a clock generation circuit, a reference character 410 indicates a clock output signal, a reference character 401 indicates a clock input signal, a reference character 402 indicates a refresh control signal, and a reference character 403 indicates a low-speed operation control signal.

The timing generation circuit 617 outputs the timing adjustment signal 616 for adjusting timings of operation, such as refresh operation or the like, of the address input circuit 611, the control circuit 613, and the refresh circuit 615. Specifically, for example, when the refresh control signal 402 is “H” (high level), then if the clock output signal 410 output from the clock generation circuit 619 transitions from “L” (low level) to “H,” the timing generation circuit 617 outputs to each part the timing adjustment signal 616 for providing an instruction to perform refresh operation.

The clock generation circuit 619 outputs the clock output signal 410 for synchronizing each part of the semiconductor storage device 623, specifically the data input/output circuit 607, the address input circuit 611, the control circuit 613, the refresh circuit 615, the timing generation circuit 617, and the like.

(Specific Configuration of Clock Generation Circuit 619)

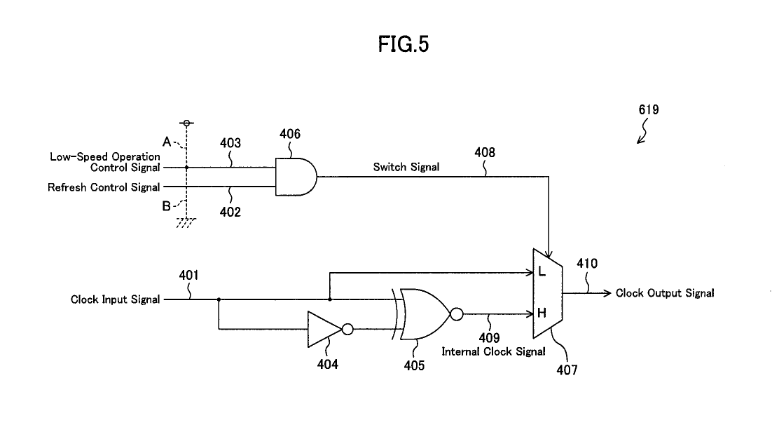

The clock generation circuit 619 has a specific configuration, such as that shown in FIG. 5.

In FIG. 5, a reference character 401 indicates a clock input signal (external clock signal), a reference character 402 indicates a refresh control signal for providing an instruction to perform refresh operation, a reference character 403 indicates a low-speed operation control signal, a reference character 404 indicates an inverter circuit (NOT circuit), a reference character 405 indicates an inversion exclusive logical OR circuit (EXNOR circuit), a reference character 406 indicates a logical AND circuit (AND circuit), a reference character 407 indicates a signal select circuit, a reference character 408 indicates a switch signal input to the signal select circuit 407, a reference character 409 indicates an internal clock signal, and a reference character 410 indicates a clock output signal (internal synchronization clock signal).

The clock output signal 410 output from the clock generation circuit 619 is generated based on the clock input signal 401, the refresh control signal 402, and the low-speed operation control signal 403 which are input from the outside of the semiconductor device 628, or from the large-scale logic circuit region 624, or the like.

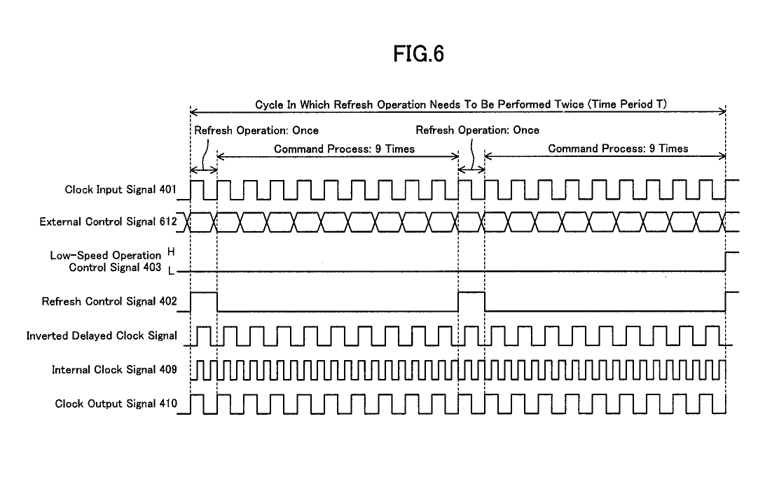

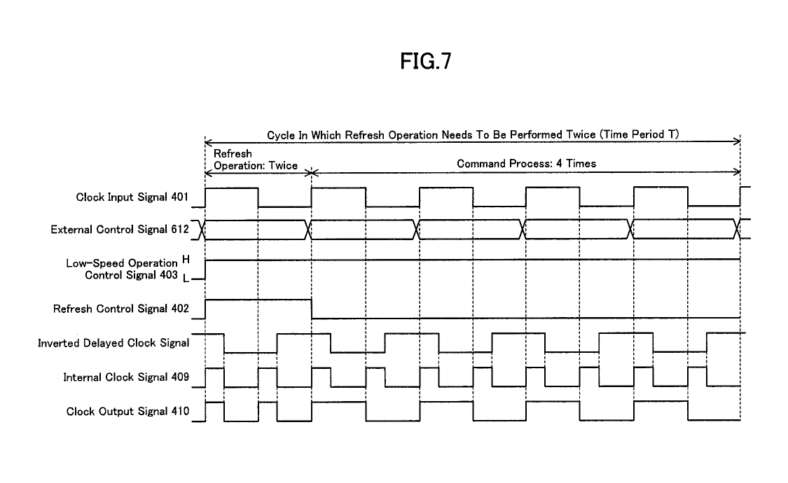

As the clock input signal 401, for example, as shown in FIGS. 6 and 7, a signal having a predetermined high frequency (FIG. 6) or a low frequency which is ¼ of that frequency (FIG. 7) is selectively input, depending on the process performed by the semiconductor device 628 or the like.

The low-speed operation control signal 403 is a signal indicating whether the frequency of the clock input signal 401 is high or low. For example, the low-speed operation control signal 403 is maintained “L” when the frequency of the clock input signal 401 is low, and “H” when high.

The refresh control signal 402 is the same signal as that which is input to the timing generation circuit 617. For example, when the frequency of the clock input signal 401 is high, the refresh control signal 402 transitions to “H” twice per time period T of 20 cycles of the high frequency signal, with the duration of “H” being one cycle for each time. When the frequency of the clock input signal 401 is low, the refresh control signal 402 is “H” once per 5 cycles of the low frequency signal, with the duration of “H” being one cycle.

When the frequency of the clock input signal 401 input to the clock generation circuit 619 is high (FIG. 6), the low-speed operation control signal 403 is maintained “L,” whereby the signal select circuit 407 selects the clock input signal 401 which is directly output as the clock output signal 410. In this case, the refresh control signal 402 transitions to “H” twice during the time period T as described above, but does not affect the clock output signal 410.

Here, for example, it is assumed that, in the semiconductor storage device 623 of this embodiment, refresh operation needs to be performed twice per time period T of 20 cycles of the high-frequency clock input signal 401, with the interval between the two occurrences of refresh operation being any length of time. In this case, the refresh control signal 402 which transitions to “H” twice during the time period T is input to the timing generation circuit 617, whereby appropriate refresh operation is performed. During the remaining 18 cycles of the time period T for which the refresh control signal 402 is “L,” a command process or the like indicated by the external control signal 612 is performed.

On the other hand, when the frequency of the clock input signal 401 input to the clock generation circuit 619 is low (FIG. 7), the low-speed operation control signal 403 is maintained “H.” In this case, when the refresh control signal 402 is “H” for one cycle of the clock input signal 401, the signal select circuit 407 selects the internal clock signal 409 for that duration. Specifically, two pulses which are “H” for a delay time of the inverter circuit 404 at timings of rising and falling of the clock input signal 401, are output as the clock output signal 410. When the clock output signal 410 is input to the timing generation circuit 617, refresh operation is appropriately performed twice per time period T as in the case where the frequency of the clock input signal 401 is high. During the time that the refresh control signal 402 is “L” and therefore refresh operation is not performed (i.e., 4 cycles per 5 cycles of the clock input signal 401), the clock input signal 401 is directly output as the clock output signal 410, and a command process or the like indicated by the external control signal 612 is performed.

(Other Parts of Semiconductor Device 628)

The large-scale logic circuit region 624 of the semiconductor device 628 includes, for example, standard cells to form circuits having an input/output (TO) function, main functions of the system LSI, and the like.

The redundancy replacement address storage circuit 625 stores an address indicating a memory cell which is to be replaced by a redundancy scheme.

A redundancy replacement address line 626 connects the redundancy replacement address storage circuit 625 to the memory array region 621.

The external terminals 627 relay signals which are input/output between the semiconductor storage device 623, the large-scale logic circuit region 624, and the like, and the outside of the semiconductor device 628.

(Operation Of Semiconductor Device 628)

When the refresh control signal 402 is “L” and therefore normal operation is performed, the clock generation circuit 619 generates the clock output signal 410 based on the clock input signal 401 input from the external terminals 627 or the like, and supplies the clock output signal 410 as a clock for synchronizing the data input/output circuit 607, the address input circuit 611, the control circuit 613, the refresh circuit 615, and the timing generation circuit 617. The control circuit 613 generates and inputs the address control signal 610 to the address input circuit 611 in accordance with the external control signal 612 in synchronization with the clock output signal 410.

The address input circuit 611 generates and inputs the row address 608 and the column address 609 to the row decoder circuit 602 and the column decoder circuit 603, respectively. A memory cell in the memory cell region 601 is selected, corresponding to values input from the row decoder circuit 602 and the column decoder circuit 603. Read/write operation is performed between the memory cell and the sense read/write amplifier circuit 604. Data input/output operation is performed between the sense read/write amplifier circuit 604 and the large-scale logic circuit region 624 via the internal data input/output line 605, the data input/output circuit 607, and the external data input/output line 606.

When the refresh control signal 402 is “H,” i.e., refresh operation is performed, then if the clock output signal 410 transitions to “H,” the timing generation circuit 617 outputs the timing adjustment signal 616 for providing an instruction to perform refresh operation. In this case, for example, the refresh circuit 615 increments the count value of an internal counter (not shown), and outputs the resultant count value as an internal address control signal 114, whereby refresh operation is performed with respect to a predetermined address region as in the case where the control circuit 113 outputs the address control signal 110. Refresh operation itself is basically similar to operation in which data is actually read or written. Refresh operation is different from data read/write operation in that read data input to the sense read/write amplifier circuit 604 is only written to the memory cell, and data input/output operation is not performed between the memory cell and the large-scale logic circuit region 624 via the internal data input/output line 605, the data input/output circuit 607, and the external data input/output line 606.

Here, in the aforementioned refresh operation, when the frequency of the clock input signal 401 is low, the refresh control signal 402 is “H” for one cycle of the clock input signal 401, and refresh operation is performed twice per time period T in accordance with the clock output signal 410 from the clock generation circuit 619. Therefore, 4 of 5 clock pulses within the time period T can be used for a command process, such as data transfer, data read/write operation, or the like, whereby a sufficient process performance of the semiconductor device 628 can be easily ensured. Moreover, by setting the frequency of the clock input signal 401 to be lower, the power consumption can be easily reduced.

(Configuration of Optical Disk Reproducing Device Including Semiconductor Device 628)

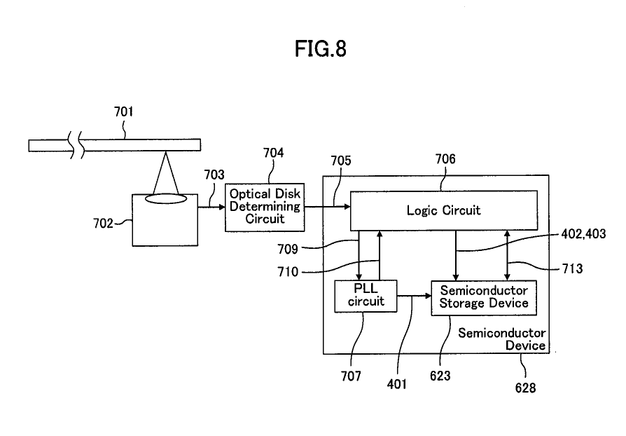

FIG. 8 is a block diagram showing a system configuration of an optical disk reproducing device which includes the semiconductor device 628 including the semiconductor storage device 623.

In FIG. 8, a reference character 701 indicates an information recording medium. The optical disk reproducing apparatus supports a plurality of types of information recording media 701 which have different data capacities, data formats, and the like and therefore have different clock signal frequencies required for data processing, such as digital video discs (or digital versatile discs (DVDs)) and compact discs (CDs), or the like. A reference character 702 indicates an optical pickup which reads information recorded on the information recording medium 701, a reference character 703 indicates a data signal corresponding to data read by the optical pickup 702, a reference character 704 indicates an optical disk determining circuit which determines the type of the information recording medium 701 based on the data signal 703, a reference character 705 indicates a data signal containing the data signal 703 and a signal indicating the determined type of the information recording medium 701, a reference character 706 indicates a circuit which processes the data signal 705, a reference character 707 indicates a phase locked loop (PLL) circuit, a reference character 709 indicates a signal with which the logic circuit 706 controls the PLL circuit 707, a reference character 710 indicates a clock output signal which the PLL circuit 707 outputs to the logic circuit 706, and a reference character 713 indicates a data bus via which data is transferred between the semiconductor storage device 623 and the logic circuit 706.

The semiconductor device 628 includes the logic circuit 706, the PLL circuit 707, and the semiconductor storage device 623. The logic circuit 706 and the PLL circuit 707 are formed in, for example, the large-scale logic circuit region 624 shown in FIG. 4 or the like.

The clock input signal 401 is output from the PLL circuit 707 and then input to the semiconductor storage device 623.

The refresh control signal 402 and the low-speed operation control signal 403 are output along with other control signals from the logic circuit 706 and then input to the semiconductor storage device 623.

(Operation of Optical Disk Reproducing Device)

Operation of the optical disk reproducing device thus configured will be described hereinafter.

Firstly, the operation in a case where the information recording medium 701 is a “medium containing a small amount of data to be processed” will be described. The optical disk determining circuit 704 determines that the information recording medium 701 is a “medium containing a small amount of data to be processed” based on the data signal 703 read from the information recording medium 701 by the optical pickup 702, and causes the data signal 705 to be, for example, “H” which indicates the determination result.

The data signal 705 which is “H” is input to the logic circuit 706. The logic circuit 706 is brought into a “mode in which signal processing can be performed at a low rate” corresponding to the “medium containing a small amount of data to be processed,” and outputs a control signal 709 which instructs the PLL circuit 707 to decrease the frequency. In response to this, the PLL circuit 707 causes the clock output signal 710 output to the logic circuit 706 and the clock input signal 401 output to the semiconductor storage device 623 to have a predetermined low frequency.

The logic circuit 706 also causes the low-speed operation control signal 403 to be “H” which indicates the clock input signal 401 input to the semiconductor storage device 623 has the low frequency. The logic circuit 706 also causes the refresh control signal 402 which instructs the semiconductor storage device 623 to perform refresh operation to be “H” for, for example, one cycle every time period T of 5 cycles of the clock input signal 401, to control the semiconductor storage device 623. Therefore, the clock generation circuit 619 (FIG. 5) of the semiconductor storage device 623 outputs two pulses as the clock output signal 410 during one cycle for which the refresh control signal 402 is “H” every time period T, and directly outputs the clock input signal 401 during four cycles for which the refresh control signal 402 is “L.” As a result, refresh operation is performed twice, and a command process or the like is performed four times.

Thus, the apparent number of clocks required for refresh operation can be reduced by a half, and clock pulses can be proportionately used for signal processing or the like in which data is transferred via the data bus 713 between the semiconductor storage device 623 and the logic circuit 706. Therefore, it is possible to provide a system in which the data transfer rate can be easily improved, the decrease in the data transfer rate can be easily reduced, or the power consumption can be easily reduced.

Next, the operation in a case where the information recording medium 701 is a “medium having a large amount of data to be processed” will be described. The optical disk determining circuit 704 determines that the information recording medium 701 is a “medium having a large amount of data to be processed” based on the data signal 703 read from the information recording medium 701 by the optical pickup 702, and causes the data signal 705 to be, for example, “L” which indicates the determination result.

The data signal 705 which is “L” is input to the logic circuit 706. The logic circuit 706 is brought into a “mode in which signal processing is performed at a high rate” corresponding to the “medium having a large amount of data to be processed,” and outputs the control signal 709 which instructs the PLL circuit 707 to increase the frequency. In response to this, the PLL circuit 707 causes the clock output signal 710 output to the logic circuit 706 and the clock input signal 401 output to the semiconductor storage device 623 to have a predetermined high frequency.

In this case, the logic circuit 706 also causes the low-speed operation control signal 403 to be “L” which indicates that the clock input signal 401 input to the semiconductor storage device 623 has a high frequency. The logic circuit 706 also causes the refresh control signal 402 which instructs the semiconductor storage device 623 to perform refresh operation to be “H” for, for example, a total of two cycles every 20 cycles of the clock input signal 401, to control the semiconductor storage device 623. Therefore, in the clock generation circuit 619 (FIG. 5) of the semiconductor storage device 623, the clock input signal 401 is selected and output as the clock output signal 410 by the signal select circuit 407 irrespective of the level of the refresh control signal 402. As a result, as in the case where the clock input signal 401 is input directly or via a buffer to the refresh circuit 615 and the like, refresh operation is performed twice and a command process or the like is performed 18 times every time period T of 20 cycles of the clock input signal 401.

### Variation of First Embodiment of the Invention

The present invention is not limited to the aforementioned case where the clock output signal 410 is switched, depending on the frequency of the clock input signal 401. Two clock pulses may be invariably output during refresh operation. Specifically, for example, a semiconductor device and an optical disk reproducing device similar to those of the first embodiment may be configured by, for example, using the clock generation circuit 619 as a common circuit or macro, and in addition, as shown by a reference character A in FIG. 5, the low-speed operation control signal 403 may be fixed to “H.” Such a configuration is applicable to a case where the clock efficiency is improved irrespective of the frequency of the clock input signal 401.

On the other hand, as shown by a reference character B in FIG. 5, the refresh control signal 402 may be fixed to “L.” In this case, the clock input signal 401 is invariably output as the clock output signal 410 via the signal select circuit 407. Therefore, for example, the clock generation circuit 619 can be caused to function as a buffer or the like using the same circuits as those of the first embodiment.

### Second Embodiment of the Invention

(Configurations of Semiconductor Device 628 and the Like)

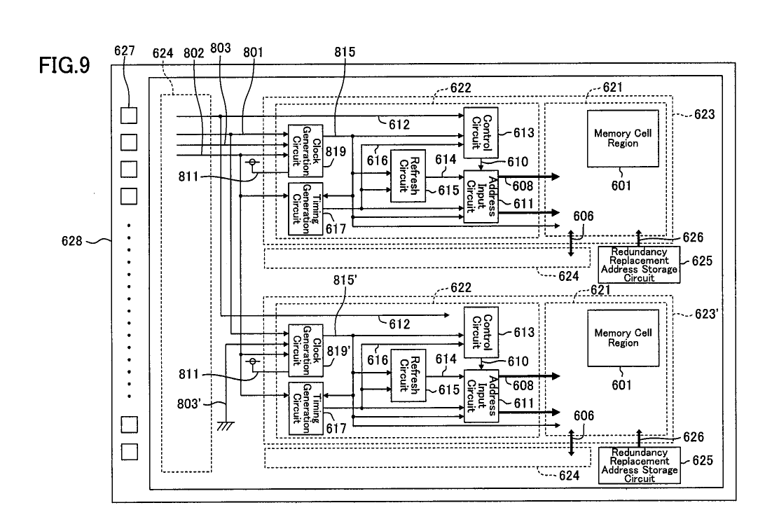

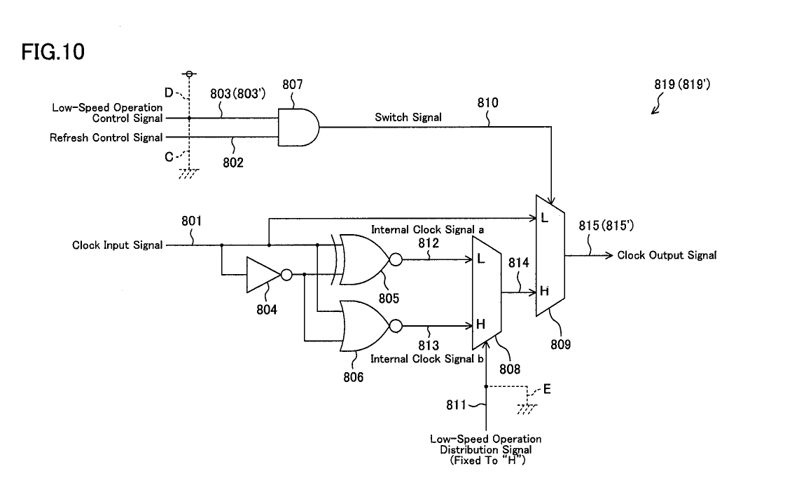

A semiconductor storage device according to the second embodiment is different from the semiconductor storage device 623 of the first embodiment (FIGS. 4 and 5) only in that, as shown in FIGS. 9 and 10, two semiconductor storage devices 623 and 623′ including clock generation circuits 819 and 819′ are provided instead of the clock generation circuit 619. As in the first embodiment, the semiconductor storage device of the second embodiment is applicable to, for example, an optical disk reproducing device, such as that shown in FIG. 8.

The clock generation circuits 819 and 819′ are different from the clock generation circuit 619 of the first embodiment in that an inversion logical OR circuit (NOR) 806, and a signal select circuit 808 whose switching is controlled in an accordance with a low-speed operation distribution signal 811, are further provided. The other components are substantially the same as those of the first embodiment. Specifically, in FIG. 10, a reference character 801 indicates a clock input signal, a reference character 802 indicates a refresh control signal for providing an instruction to perform refresh operation, reference characters 803 and 803′ each indicate a low-speed operation control signal, a reference character 804 indicates an inverter circuit (NOT circuit), a reference character 805 indicates an inversion exclusive logical OR circuit (EXNOR circuit), a reference character 806 indicates an inversion logical OR circuit (NOR circuit), a reference character 807 indicates a logical AND circuit (AND circuit), reference characters 808 and 809 each indicate a signal select circuit, a reference character 810 indicates a switch signal input to the signal select circuit 809, a reference character 811 indicates a low-speed operation distribution signal which is a switch signal input to the signal select circuit 808, a reference character 812 indicates an internal clock signal “a,” a reference character 813 indicates an internal clock signal “b,” a reference character 814 indicates an output signal of the signal select circuit 808, and reference characters 815 and 815′ each indicate a clock output signal.

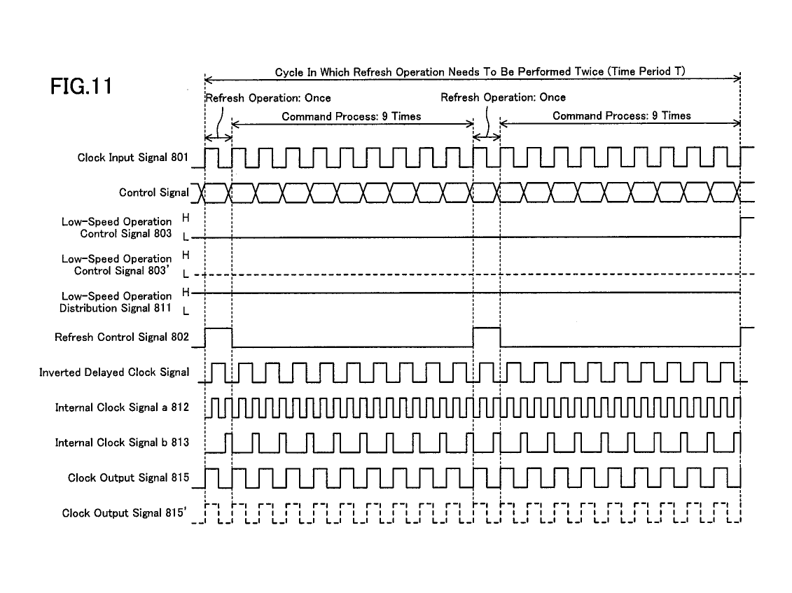

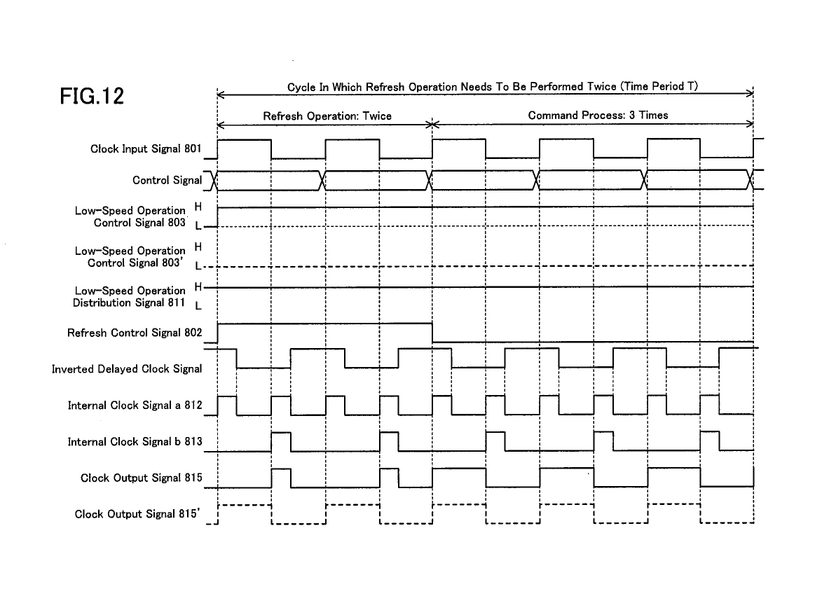

FIGS. 11 and 12 are diagrams showing waveforms of input/output signals of the clock generation circuits 819 and 819′ and internal signals. Specifically, the clock generation circuits 819 and 819′ receive the clock input signal 801, the refresh control signal 802, the low-speed operation control signals 803 and 803′, and the low-speed operation distribution signal 811 shown in FIGS. 11 and 12, and outputs the clock output signals 815 and 815′.

Here, it is assumed that refresh timing needs to satisfy conditions that refresh operation needs to be performed twice per time period T as in the first embodiment.

A signal having a predetermined high frequency or a low frequency which is ¼ of the high frequency is selectively input as the clock input signal 801 to the clock generation circuits 819 and 819′, depending on the determined type of the information recording medium or the like, as in the first embodiment. The low-speed operation control signal 803 input to the clock generation circuit 819 is maintained “L” when the frequency of the clock input signal 401 is high, and “H” when low. On the other hand, the low-speed operation control signal 803′ input to the clock generation circuit 819′ is invariably fixed to “L” as indicated by a reference character C in FIG. 10, for example. The low-speed operation distribution signal 811 is invariably fixed to “H” in both of the clock generation circuits 819 and 819′. The refresh control signal 802 transitions to “H” twice during the time period T when the frequency of the clock input signal 801 is high as in the first embodiment, and is “H” for two cycles of the clock input signal 801 when the frequency of the clock input signal 801 is low.

(Operation of Semiconductor Device 628 and the Like)

Refresh Time Period and Other Time Periods when Clock Frequency is High

When the frequency of the clock input signal 801 is high (FIG. 11), the clock input signal 801 is directly output as the clock output signals 815 and 815′ in both of the clock generation circuits 819 and 819′ no matter whether it is during the refresh time period.

Specifically, in the clock generation circuit 819′, the low-speed operation control signal 803′ is invariably fixed to “L,” and therefore, the clock input signal 801 is selected and output by the signal select circuit 809.

In the clock generation circuit 819, when the frequency of the clock input signal 801 is high, the low-speed operation control signal 803 is maintained “L,” and therefore, the clock input signal 801 is selected and output.

Therefore, as in the first embodiment, the refresh control signal 802 transitions to “H” twice during the time period T, and appropriate refresh operation is performed at timings of rising of the clock output signals 815 and 815′, and a command process or the like is performed 18 times during the time that the refresh control signal 802 is “L.”

<Time Periods Other than Refresh Time Period when Clock Frequency is Low>

Even when the frequency of the clock input signal 801 is low (FIG. 12), the clock input signal 801 is directly output as the clock output signals 815 and 815′ during time periods other than the refresh time period in both of the clock generation circuits 819 and 819′.

Specifically, in the clock generation circuit 819′, the low-speed operation control signal 803′ is invariably fixed to “L,” whereby the signal select circuit 808 selects and outputs the clock input signal 801.

In the clock generation circuit 819, the refresh control signal 802 is “L,” and therefore, the clock input signal 801 is similarly selected and output. Thus, a command process or the like is performed three times per time period T.

<Refresh Time Period when Clock Frequency is Low>

During the refresh time period when the frequency of the clock input signal 801 is low (FIG. 12), in the clock generation circuit 819′ the low-speed operation control signal 803′ is also invariably fixed to “L,” and therefore, the clock input signal 801 is directly output as the clock output signal 815′.

On the other hand, in the clock generation circuit 819, the low-speed operation distribution signal 811 is fixed to “H,” and the low-speed operation control signal 803 and the refresh control signal 802 transition to “H,” so that the switch signal 810 transitions to “H,” and therefore, the signal select circuit 808 and the signal select circuit 809 select the internal clock signal “b” 813 and the output signal 814, respectively. The internal clock signal “b” 813 is the output of the inversion logical OR circuit to which the clock input signal 801 and its inverted signal are input, and therefore, a pulse which is “H” for a delay time of the inverter circuit 804 is generated and output as the clock output signal 815 at a timing of falling of the clock input signal 801.

In this case, in the semiconductor storage device 623′, refresh operation is performed at a timing of rising of the clock input signal 801, and in the semiconductor storage device 623, refresh operation is performed at a timing of falling of the clock input signal 801. Specifically, when the frequency of the clock input signal 801 is low, refresh operation is performed at different timings, and therefore, timings at which a refresh current is consumed are distributed to reduce the concentration of the power consumption, whereby the average current consumption of the semiconductor device can be reduced.

### Variation of Second Embodiment of the Invention

In the aforementioned example, in the semiconductor storage device 623, the low-speed operation control signal 803 is “H” only when the frequency of the clock input signal 801 is low. The present invention is not limited to this. For example, as indicated by a reference character D in FIG. 10, the low-speed operation control signal 803 may be invariably fixed to “H,” and refresh operation may be invariably performed at different timings in the semiconductor storage devices 623 and 623′ irrespective of the frequency of the clock input signal 801.

Alternatively, a single or a plurality of the semiconductor storage devices 623 in which the low-speed operation control signal 803 is fixed to “L” may be provided. Specifically, in this case, as in the variation of the first embodiment, the same circuits as those of the second embodiment may be used and the clock generation circuit 619 may be caused to function as a buffer or the like.

Moreover, the present invention is not limited to the aforementioned case where the low-speed operation distribution signal 811 is fixed to “H.” Alternatively, as indicated by a reference character E in FIG. 10, the low-speed operation distribution signal 811 may be fixed to “L.” In this case, the signal select circuit 808 invariably selects the internal clock signal “a” 812, and therefore, the clock generation circuits 819 and 819′ can be operated in accordance with the refresh control signal 802 and the low-speed operation control signal 803 in the same manner as that of the clock generation circuit 619 of the first embodiment or its variation, to improve the clock efficiency. As a result, for example, the circuit can be easily shared.

Moreover, the present invention is not limited to the case where the low-speed operation distribution signal 811 is fixed to “H” or “L.” Alternatively, for example, the low-speed operation distribution signal 811 may be dynamically controlled by the logic circuit 706 or the like, depending on required command process performance or current consumption so that refresh operation is performed twice per clock cycle as in the first embodiment, or at different timings in a plurality of the semiconductor storage devices 623. Specifically, as a result, for example, the apparent number of clocks required for refresh operation can be reduced by a half, and timings at which a refresh current is consumed can be distributed. Therefore, an optical disk reproducing device employing the semiconductor device can be configured to reduce or distribute the power consumption while reducing the decrease in the data transfer rate.

<<Other Features>>

As described above, a semiconductor storage device is provided in each of a single or a plurality of semiconductor devices, and the “H” and “L” states of the low-speed operation distribution signal 811 and the low-speed operation control signals 803 and 403 are fixed or dynamically controlled in various manners with respect to each semiconductor storage device to combine the low-speed operation control and the low-speed distribution control in various manners. As a result, for example, low power consumption optimal to the optical disk reproducing device or the like can be achieved.

While, in the aforementioned embodiments, an example in which a DRAM is used has been described, the present invention is not limited to the DRAM, and any memory cells requiring refresh operation can be considerably easily used.

While, in the aforementioned embodiments, an example in which an optical disk reproducing device is used has been described, the present invention is not limited to the optical disk reproducing device, and can also be considerably easily applied to, for example, a semiconductor device which is provided in a system having a different data transfer rate to a memory according to operation specifications.

According to the aforementioned embodiments, it is possible to efficiently develop semiconductor devices for use in a wide variety of applications encompassing consumer products and in-car products mainly including AV apparatuses, which have short product cycles, and particularly optical disk recording and reproducing devices, digital televisions, digital cameras, digital audio apparatuses, and the like. As a result, the profitability can be improved.

### INDUSTRIAL APPLICABILITY

The semiconductor storage device of the present invention is useful for, for example, a reduction in the power consumption, an improvement in the data transfer rate, and the like of a semiconductor device.

### DESCRIPTION OF REFERENCE CHARACTERS

401 Clock Input Signal
402 Refresh Control Signal
403 Low-Speed Operation Control Signal
404 Inverter Circuit
405 Inversion Exclusive Logical OR Circuit
406 Logical AND circuit
407 Signal Select Circuit
408 Switch Signal
409 Internal Clock Signal
410 Clock Output Signal
601 Memory Cell Region
602 Row Decoder Circuit
603 Column Decoder Circuit
604 Sense Read/Write Amplifier Circuit
605 Internal Data Input/Output Line
606 Outer Data Input/Output Line
607 Data Input/Output Circuit
608 Row Address
609 Column Address
610 Address Control Signal
611 Address Input Circuit
612 External Control Signal
613 Control Circuit
614 Internal Address Control Signal
615 Refresh Circuit
616 Timing Adjustment Signal
617 Timing Generation Circuit
619 Clock Generation Circuit
621 Memory Array Region
622 Control Region
623 Semiconductor Storage Device
623′ Semiconductor Storage Device
624 Large-Scale Logic Circuit Region
625 Redundancy Replacement Address Storage Circuit
626 Redundancy Replacement Address Line
627 External Terminals
628 Semiconductor Device
701 Information Recording Medium
702 Optical Pickup
703 Data Signal
704 Optical Disk Determining Circuit
705 Data Signal
706 Logic Circuit
707 PLL circuit
709 Control Signal
710 Clock Output Signal
713 Data Bus
801 Clock Input Signal
802 Refresh Control Signal
803 Low-Speed Operation Control Signal
803′ Low-Speed Operation Control Signal
804 Inverter Circuit
805 Inversion Exclusive Logical OR Circuit
806 Inversion Logical OR Circuit
808 Signal Select Circuit
809 Signal Select Circuit
810 Switch Signal
811 Low-Speed Operation Distribution Signal
812 Internal Clock Signal “a”
813 Internal Clock Signal “b”
814 Output Signal
815 Clock Output Signal
815′ Clock Output Signal
819 Clock Generation Circuit
819′ Clock Generation Circuit

1. A semiconductor storage device including a memory cell and having a function of refreshing the memory cell, comprising:
a clock generation circuit configured to receive a first clock, generate a second clock based on an inversion of the first clock, and output the second clock,
wherein
the semiconductor storage device performs operation of the refresh function in synchronization with at least one of the first and second clocks.

2. The semiconductor storage device of claim 1, further comprising:
a select circuit configured to select one of the first and second clocks in synchronization with which the refresh operation is to be performed, in accordance with a control signal.

3. A semiconductor device comprising:
the semiconductor storage device of claim 2;
a logic circuit; and
an IO block including an input/output circuit configured to receive and output a signal from and to the outside, and an electrode pad connected to the input/output circuit,
wherein
an external signal input via the IO block is input to the logic circuit, and the control signal which controls the selection of the select circuit is generated.

4. The semiconductor device of claim 3, further comprising:
a PLL circuit configured to generate a clock having a frequency which is controlled in accordance with the external signal input via the IO block, and input the clock to the semiconductor storage device and the logic circuit.

5. The semiconductor device of claim 3, comprising any combination of:
the semiconductor storage device configured to perform the refresh operation in synchronization with the first clock;
the semiconductor storage device configured to perform the refresh operation in synchronization with the second clock.

6. An optical disk reproducing device comprising:
a semiconductor device including a semiconductor storage circuit having a function of refreshing a memory cell, a logic circuit, an IO block including an input/output circuit configured to receive and output a signal and an electrode pad connected to the input/output circuit, and a PLL circuit configured to generate a clock and change a frequency of the clock in accordance with a control signal;
an optical pickup; and
a circuit configured to output a signal which can be used to discriminate between a plurality of types of information recording media based on a data signal read by the optical pickup,
wherein
the semiconductor storage circuit includes a clock generator configured to receive a first clock, generate a second clock based on an inversion of the first clock, and output the second clock, and a select circuit configured to select one of the first and second clocks in synchronization with which the refresh operation is to be performed, in accordance with a control signal,
the signal which can be used to discriminate between a plurality of types of information recording media is input as an external signal to the IO block of the semiconductor device, and
the external signal is input to the logic circuit, the control signal to be input to the select circuit of the semiconductor storage device is generated, and the refresh operation of the semiconductor storage device is controlled in accordance with the control signal.

7. An optical disk reproducing device comprising:
a semiconductor device including a semiconductor storage circuit having a function of refreshing a memory cell, a logic circuit, an IO block including an input/output circuit configured to receive and output a signal and an electrode pad connected to the input/output circuit, and a PLL circuit configured to generate a clock and change a frequency of the clock in accordance with a control signal;
an optical pickup; and
a circuit configured to output a signal which can be used to discriminate between a plurality of types of information recording media based on a data signal read by the optical pickup,
wherein
the semiconductor storage circuit includes a clock generator configured to receive a first clock, generate a second clock based on an inversion of the first clock, and output the second clock, and a select circuit configured to select one or both of the first and second clocks in synchronization with which the refresh operation is to be performed, in accordance with a control signal,
the signal which can be used to discriminate between a plurality of types of information recording media is input as an external signal to the IO block of the semiconductor device, and
a frequency of a clock input to the semiconductor storage device and the logic circuit is changed in accordance with the external signal.

8. The semiconductor storage device of claim 1, wherein
the clock generation circuit generates the second clock containing two pulses per clock cycle.

9. The semiconductor storage device of claim 8, wherein
the clock generation circuit includes
a NOT circuit configured to invert the first clock to output an inverted signal, and
an EXNOR circuit configured to generate the second clock based on the first clock and the inverted signal.

10. The semiconductor storage device of claim 8, wherein
the clock generation circuit includes
a selector configured to select one of the first and second clocks.

11. The semiconductor storage device of claim 10, wherein
the selector performs the selection in accordance with a control signal input from the outside of the semiconductor storage device.

12. The semiconductor storage device of claim 10, wherein
the selector is configured to fixedly select one of the first and second clocks during the refresh operation.

13. The semiconductor storage device of claim 8, wherein
the clock generation circuit includes a selector,
the clock generation circuit is configured to generate a third clock which transitions at a timing different from a transition timing of the first clock to cause the refresh operation, and
the selector selects one of the first, second, and third clocks.

14. The semiconductor storage device of claim 13, wherein
the clock generation circuit includes
a NOT circuit configured to invert the first clock to generate and output an inverted signal, and
a NOR circuit configured to generate the third clock based on the first clock and the inverted signal.

15. The semiconductor storage device of claim 13, wherein
the selector selects one of the first and second clocks.

16. The semiconductor storage device of claim 13, wherein
first and second pairs of the memory cell and the clock generation circuit are provided,
the selector for the first pair fixedly selects the first clock, and
the selector for the second pair selects one of the first and third clocks during the refresh operation.

17. The semiconductor storage device of claim 16, wherein
the selector for the second pair is configured to fixedly select the third clock during the refresh operation.

18. A semiconductor device comprising:
the semiconductor storage device of claim 10,
wherein
the selector selects the first clock when the first clock has a first frequency, and the second clock when the first clock has a second frequency lower than the first frequency.

19. An optical disk reproducing device comprising:
the semiconductor device of claim 18;
an optical pickup configured to read information recorded in a recording medium; and
a determination circuit configured to determine a frequency of a clock to be supplied to the semiconductor storage device in the semiconductor device so that the information read from the recording medium is processed, and output a determination signal,
wherein
the selector selects the first or second clock, depending on the determination signal.

20. The optical disk reproducing device of claim 19, further comprising:
a PLL circuit configured to generate the first clock having a frequency depending on the determination signal.
